(19) United States
(12) Patent Application Publication
(10) Pub. No.: US 2024/0269798 A1
(43) Pub. Date: Aug. 15, 2024

(54) CONDITIONING APPARATUS

(71) Applicant: Samsung Electronics Co., Ltd., Suwon-si (KR)

(72) Inventors: Hyuntae Lee, Suwon-si (KR); Domin Kim, Suwon-si (KR); Sungyong Park, Suwon-si (KR); Jubong Lee, Suwon-si (KR); Jaemin Jung, Suwon-si (KR); Hoseop Choi, Suwon-si (KR)

(21) Appl. No.: 18/402,471

(22) Filed: Jan. 2, 2024

(30) Foreign Application Priority Data
Feb. 9, 2023 (KR) 10-2023-0017373

(51) Int. Cl. B24B 37/20

(52) U.S. Cl. CPC B24B 37/20

(57) ABSTRACT

A conditioning apparatus includes an arm configured to be rotated by an actuator, a gimbaling part disposed at one end of the arm and disposed such that a lower end thereof protrudes outwardly of the arm and an abrasive disc is installed thereon, a frame unit connected to the gimbaling part, a rotation driving unit connected to the gimbaling part and configured to transfer driving force for rotating the abrasive disc, a load applying unit connected to the frame unit and configured to elevate the frame unit, and a universal joint connecting the gimbaling part to the rotation driving unit, wherein the universal joint separates a center of gravity of the rotation driving unit from a center of gravity of the gimbaling part.

### CROSS-REFERENCE TO RELATED APPLICATION(S)

This application claims benefit of priority under 35 U.S.C. § 119 to Korean Patent Application No. 10-2023-0017373, filed on Feb. 9, 2023, in the Korean Intellectual Property Office, the disclosure of which is incorporated herein by reference in its entirety.

### BACKGROUND

The present inventive concept relates to a conditioning apparatus.

In manufacturing semiconductor devices, a chemical-mechanical polishing (CMP) process using a CMP device is used to flatten a wafer. Also, the CMP process is a process of polishing surfaces of wafers using a chemical-mechanical interaction between the wafers and CMP pads.

Meanwhile, a conditioning apparatus sweeping over the CMP pads has been used to regenerate the CMP pads during the CMP process. However, in the conditioning apparatus of the related art, tilting of an abrasive disc occurs due to frictional contact between the CMP pads and the abrasive disc. In this case, scratches and uneven wear occur on the CMP pads, and fatigue failure and plastic deformation occur.

In order to solve this problem, a conditioning apparatus maintaining the abrasive disc in a balanced state by compensating for lifting of the abrasive disc caused by frictional contact and sweep with the CMP pads by pneumatic pressure has been developed.

However, the developed conditioning apparatus has a problem in that a perturbation phenomenon may occur.

### SUMMARY

An aspect of the present inventive concept is to provide a conditioning apparatus capable of reducing the occurrence of a perturbation phenomenon.

According to an aspect of the present inventive concept, a conditioning apparatus includes: an arm configured to be rotated by an actuator; a gimbaling part disposed at one end of the arm and disposed such that a lower end thereof protrudes outwardly of the arm and an abrasive disc is installed thereon; a frame unit connected to the gimbaling part; a rotation driving unit connected to the gimbaling part and configured to transfer driving force for rotating the abrasive disc; a load applying unit connected to the frame unit and configured to elevate the frame unit; and a universal joint connecting the gimbaling part to the rotation driving unit, wherein the universal joint separates a center of gravity of the rotation driving unit from a center of gravity of the gimbaling part.

According to an aspect of the present inventive concept, a conditioning apparatus includes: an arm configured to be rotated by an actuator; a gimbaling part disposed at one end of the arm and disposed such that a lower end thereof protrudes outwardly of the arm and an abrasive disc is installed thereon; a frame unit connected to the gimbaling part; a rotation driving unit connected to the gimbaling part and configured to transfer driving force for rotating the abrasive disc; a load applying unit connected to the frame unit and configured to elevate the frame unit; and a universal joint connecting the gimbaling part to the rotation driving unit, wherein the universal joint includes a first yoke connected to the gimbaling part, a second yoke disposed above the first yoke and connected to the rotation driving unit, and a cross shaft connecting the first yoke to the second yoke, wherein the universal joint separates the center of gravity of the rotation driving unit from the center of gravity of the gimbaling part, wherein the gimbaling part includes a disc holder having one surface on which the abrasive disc is installed and an other surface on which a protrusion is provided, a coupling shaft portion connected to the universal joint extending from the protrusion, and wherein the center of gravity of the gimbaling part and the center of the gimbaling part are disposed within the protrusion.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a schematic diagram illustrating a conditioning apparatus according to an example embodiment;

FIG. 2 is an enlarged view illustrating portion A of FIG. 1;

FIG. 3 is a perspective view illustrating a gimbaling part provided in a conditioning apparatus according to an example embodiment;

FIG. 4 is an exploded perspective view illustrating a gimbaling part provided in a conditioning apparatus according to an example embodiment;

FIG. 5 is a perspective view illustrating a frame unit included in the conditioning apparatus according to an example embodiment;

FIG. 6 is an exploded perspective view illustrating a frame unit provided in the conditioning apparatus according to an example embodiment;

FIG. 7 is a perspective view illustrating a universal joint and a rotation driving unit provided in a conditioning apparatus according to an example embodiment;

FIG. 8 is a perspective view illustrating a load applying unit provided in a conditioning apparatus according to an example embodiment;

FIG. 9 is a graph illustrating performance of a conditioning apparatus according to the related art; and

FIG. 10 is a graph illustrating performance of a conditioning apparatus according to an example embodiment of the present inventive concept.

### DETAILED DESCRIPTION

Hereinafter, example embodiments of the present inventive concept will be described with reference to the accompanying drawings. Like numerals refer to like elements throughout the specification and drawings.

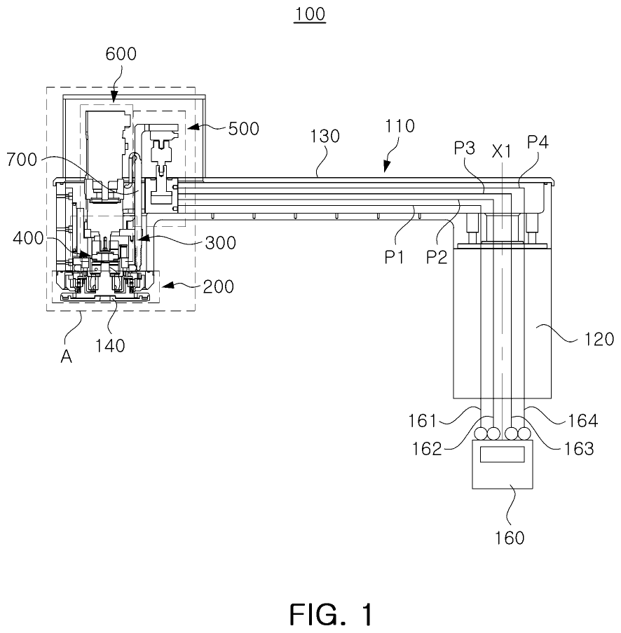

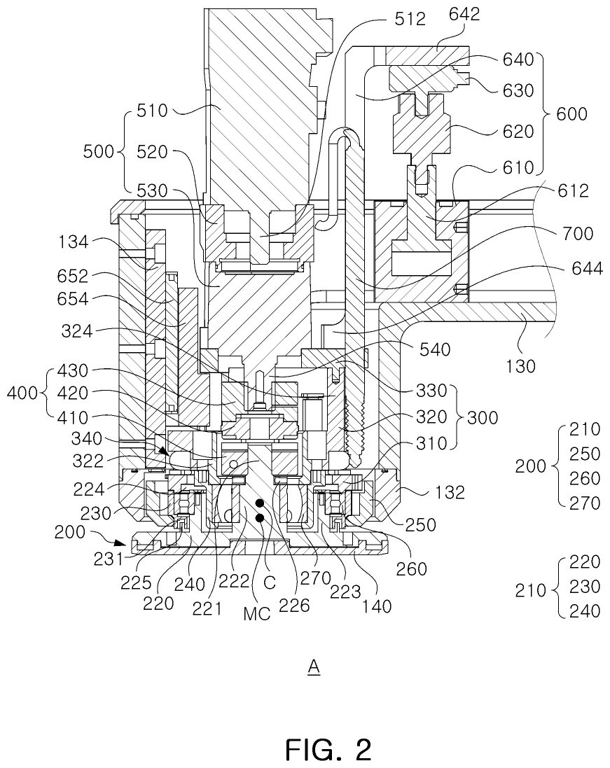

FIG. 1 is a configuration diagram illustrating a conditioning apparatus according to an example embodiment, and FIG. 2 is an enlarged view illustrating portion A of FIG. 1.

Referring to FIGS. 1 and 2, a conditioning apparatus 100 according to an embodiment of the present inventive concept includes an arm 110, a gimbaling part 200, a frame unit 300, a universal joint 400, a rotation driving unit 500, and a load applying unit 600.

The arm 110 is rotated by an actuator 120. As an example, the arm 110 may include a case 130 having an internal space, and at one end of the case 130, the gimbaling part 200, the frame unit 300, the universal joint 400, the rotation driving unit 500, and the load applying unit 600 may be provided. Meanwhile, the arm 110 may be rotated about a first axis X1 by the actuator 120. Accordingly, an abrasive disc 140 installed on the gimbaling part 200 may move on a chemical-mechanical polishing (CMP) pad (not shown).

The gimbaling part 200 is disposed so that a lower end thereof is exposed to the outside of the case 130, and the abrasive disc 140 is installed in the gimbaling part 200. Meanwhile, the gimbaling part 200 may be rotated by the rotation driving unit 500. A detailed description of the gimbaling part 200 is described below.

The frame unit 300 may be connected to the gimbaling part 200. In addition, the frame unit 300 may be connected to the load applying unit 600, and may be moved up and down by the load applying unit 600. Accordingly, the gimbaling part 200 and the frame unit 300 may be moved up and down by the load applying unit 600. Meanwhile, details of the frame unit 300 are described below.

The universal joint 400 may serve to connect the rotation driving unit 500 to the gimbaling part 200, and the center of gravity of the rotation driving unit 500 and the center of gravity of the gimbaling part 200 may be separated by the universal joint 400. Accordingly, a distance between the center of gravity of the gimbaling part 200 and the center of the gimbaling part 200 may be reduced. Details of the universal joint 400 are described below.

The rotation driving unit 500 is connected to the gimbaling part 200 to generate driving force for rotating the gimbaling part 200 to rotate the gimbaling part 200. Details of the rotation driving unit 500 are described below.

The load applying unit 600 is connected to the frame unit 300 to elevate or lower the frame unit 300. Accordingly, the gimbaling part 200 connected to the frame unit 300 may also be elevated or lowered in conjunction with the frame unit 300. Accordingly, pressure applied by the abrasive disc 140 installed on the gimbaling part 200 to the CMP pad may be adjusted. Details of the load applying unit 600 are also be described below.

Meanwhile, the conditioning apparatus 100 may further include a displacement sensor 700 detecting an inclination angle of the gimbaling part 200. The displacement sensor 700 may serve to transmit information on a separation distance from the frame unit 300 so that a main controller (not shown) may calculate the inclination angle of the gimbaling part 200 through the separation distance from the frame unit 300.

Hereinafter, the gimbaling part, 200, the frame unit 300, the universal joint 400, the rotation driving unit 500, and the load applying unit 600 included in the conditioning apparatus 100 are described in detail with reference to the accompanying drawings.

### Gimbaling Part

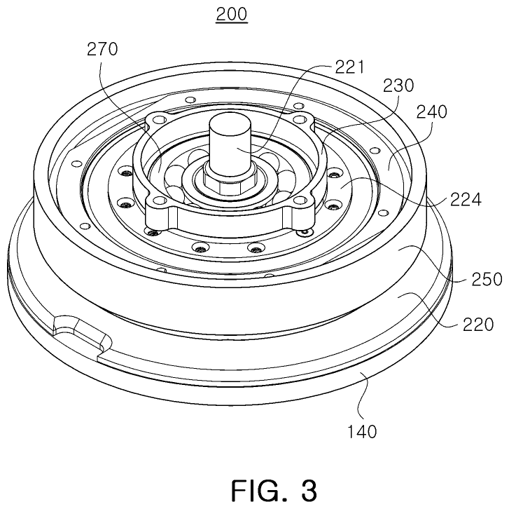

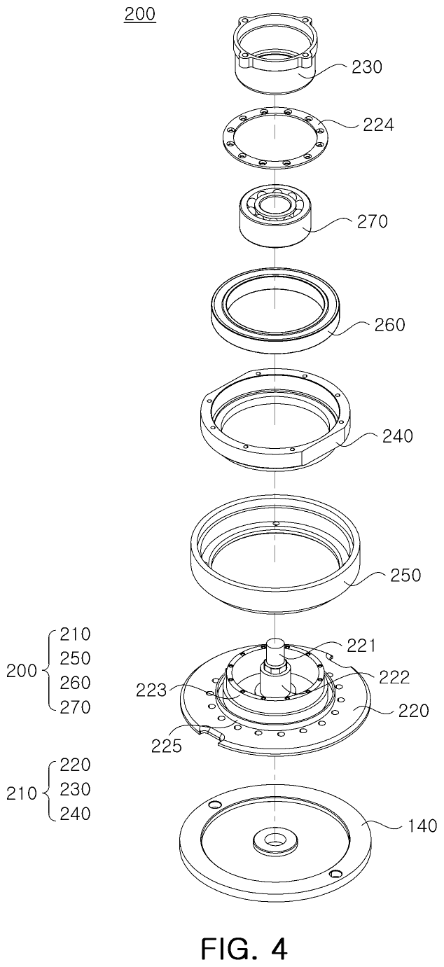

FIG. 3 is a perspective view illustrating a gimbaling part included in a conditioning apparatus according to an example embodiment, and FIG. 4 is an exploded perspective view illustrating a gimbaling part included in a conditioning apparatus according to an example embodiment.

Referring to FIGS. 3 and 4 together with FIG. 2, the gimbaling part 200 may include, for example, a disc holder 210, a housing 250, a first bearing 260, and a second bearing 270.

The disc holder 210 may have one surface on which the abrasive disc 140 is installed, and may include a coupling shaft portion 221 connected to the universal joint 400. For example, the abrasive disc 140 may be provided on a lower surface of the disc holder 210, and the coupling shaft portion 221 may be located on a surface of the disc holder 210 that is opposite to a side on which the lower surface is located. Meanwhile, the disc holder 210 may include, for example, a disc holder body 220, a first installation member 230, and a second installation member 240.

The disc holder body 220 includes a protrusion 222 at the center of the other surface thereof, and the coupling shaft portion 221 extends from the protrusion 222. For example, the protrusion may be located on the side of the disc holder 210 that is opposite to the side on which the lower surface is located. In addition, the protrusion 222 has a stepped lower end for installation of the second bearing 270, and an inner ring side of the second bearing 270 may be seated on a lower end portion of the stepped protrusion 222. The second bearing 270 may surround the stepped protrusion 222. Meanwhile, the disc holder body 220 may include a protruding wall portion 223 disposed to surround the protrusion 222 and forming a space into which the first bearing 260 is inserted together with the first installation member 230. The protruding wall portion 223 may surround the second bearing 270, and the first bearing 260 may surround an upper portion of the protruding wall portion 223. Also, a first fixing member 224 for preventing separation of the first bearing 260 may be installed on an upper surface of the protruding wall portion 223. The first fixing member 224 may overlap a portion of the first bearing 260. In addition, the disc holder body 220 may include a protruding jaw 225 disposed to surround the protruding wall portion 223. The protruding jaw 225 may be inserted into a groove portion 231 provided in the first installation member 230. In addition, a second fixing member 226 for preventing separation of the second bearing 270 may be installed at a lower end portion of the coupling shaft portion 221. Meanwhile, the center of gravity MC of the gimbaling part 200 and the center C of the gimbaling part 200 may be disposed within the protrusion 222. As an example, the center of gravity MC of the gimbaling part 200 may be disposed lower than the center C of the gimbaling part 200. When viewed in cross-section, the center C of the gimbaling part 200 may be the halfway point of outermost opposite vertical sides of the gimbaling part 200 and the halfway point between a lowermost surface and an uppermost surface of the gimbaling part 200.

The first installation member 230 is fixed to the frame unit 300 (refer to FIG. 2) and forms a space in which the first bearing 260 is inserted and installed together with the protruding wall portion 223. Also, as described above, the first installation member 230 may be provided with the groove portion 231 into which the protruding jaw 225 is inserted. As an example, the first installation member 230 may be fixed to and installed in the first frame 310 through bolts (not shown).

The second installation member 240 is fixed to and installed in the frame unit 300 and forms a space in which the second bearing 270 is inserted and installed together with the protrusion 222. As an example, the second installation member 240 may be fixed to and installed in the second frame 320 through bolts (not shown).

The housing 250 is disposed outside the disc holder 220. As an example, the housing 250 may be coupled to the first installation member 230 and may be disposed inside a protective member 132 installed at the end of the case 130 of the arm 110. In addition, an internal surface of the housing 250 may have a plurality of steps to prevent interference with components disposed inside.

The first bearing 260 is disposed inside the housing 250. As an example, the first bearing 260 may be inserted into and disposed in a space formed by the first installation member 230 and the protruding wall portion 223. As an example, the first bearing 260 may be a deep groove ball bearing. Since the first bearing 260 is configured as a deep groove ball bearing, the disc holder 220 may rotate more smoothly even when a thrust load generated when the disc holder 220 tilts is applied.

The second bearing 270 is disposed inside the first bearing 260. As an example, the second bearing 270 may be inserted into and disposed in a space formed by the second installation member 240 and the protrusion 222. As an example, the second bearing 270 may be a self-aligning ball bearing. As such, since the second bearing 270 is configured as a self-aligning ball bearing, the disc holder 220 may tilt more smoothly.

### Frame Unit

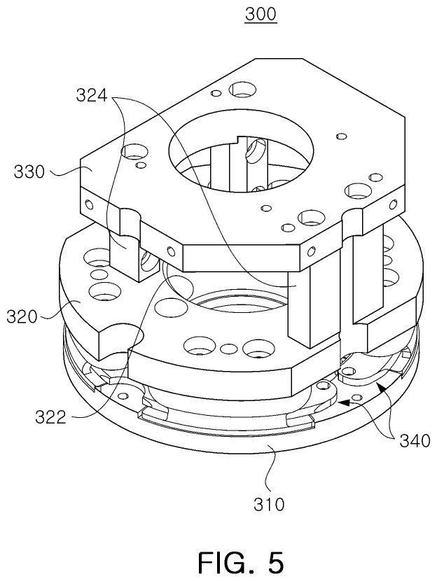

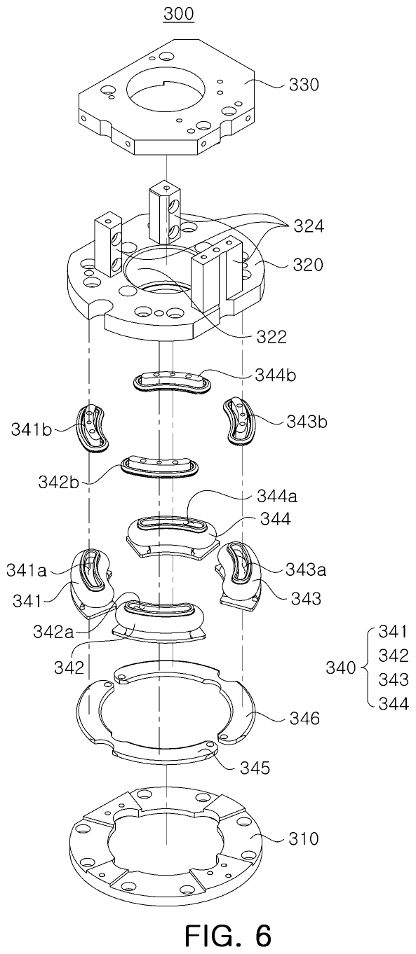

FIG. 5 is a perspective view illustrating a frame unit included in the conditioning apparatus according to an example embodiment, and FIG. 6 is an exploded perspective view illustrating a frame unit included in the conditioning apparatus according to an example embodiment.

Referring to FIGS. 5 and 6 together with FIG. 2, the frame unit 300 includes, for example, a first frame 310, a second frame 320, and a third frame 330.

The first frame 310 may have a hollow ring shape and may be disposed above the gimbaling part 200 described above. Meanwhile, an air bag module 340 may be disposed in a space between the first frame 310 and the second frame 320. When the gimbaling part 200 tilts, the air bag module 340 serves to compensate for the tilted gimbaling part 200 to be level. To this end, the air bag module 340 may include at least two air bag blocks 340 having different pressures between the first frame 310 and the second frame 320. As an example, the air bag module 340 may include four air bag modules 340. Meanwhile, as shown in more detail in FIG. 6, the air bag module 340 may include a first air bag block 341, a second air bag block 342, a third air bag block 343, and a fourth air bag block 344, a first airline 161 (refer to FIG. 1), a second airline 162 (refer to FIG. 1), a third airline 163 (refer to FIG. 1), a fourth airline 164 (refer to FIG. 1), and a controller 160 (refer to FIG. 1). Each of the first airline 161, the second airline 162, the third airline 163, and the fourth airline 164 may be a hose or a tube that carries air under pressure.

Meanwhile, the first air bag block 341, the second air bag block 342, the third air bag block 343, and the fourth air bag block 344 may be arranged between the first frame 310 and the second frame 320, and each may have substantially the same shape and size. Meanwhile, since the space formed between the first frame 310 and the second frame 320 has a substantially ring shape, the first air bag block 341, the second air bag block 342, the third air bag block 343, the fourth air bag block 344 may form a substantially circular arc shape. However, the first air bag block 341, the second air bag block 342, the third air bag block 343, and the fourth air bag block 344 are not limited to forming a circular shape and may be variously changed to correspond to a shape of the space formed between the first frame 310 and the second frame 320.

The first air bag block 341 may have a first air bag 341a. As an example, the first air bag 341a may be provided in the first air bag block 341. Also, the first air bag 341a may be connected to the first airline 161, and first air pressure P1 (refer to FIG. 1) may be supplied to the first air bag 341a. For example, the first airline 161 may supply pressurized air to the first air bag 341a as the first air pressure P1. Meanwhile, the first air pressure P1 transferred to the first air bag 341a through the first airline 161 may be controlled by the controller 160.

As an example, an upper portion of the first air bag 341a may be opened, and an upper cover 341b covering the first air bag 341a may be provided above the opened first air bag 341a.

The second air bag block 342 may have a second air bag 342a. As an example, the second air bag 342a may be provided in the second air bag block 342. Also, the second air bag 342a may be connected to the second airline 162, and a second air pressure P2 (refer to FIG. 1) may be supplied to the second air bag 342a. For example, the second airline 162 may supply pressurized air to the second air bag 342a as the second air pressure P2. Meanwhile, the second air pressure P2 transferred to the second air bag 342a through the second airline 162 may be controlled by the controller 160.

As an example, an upper portion of the second air bag 342a may be opened, and an upper cover 342b covering the second air bag 342a may be provided above the opened second air bag 342a.

The third air bag block 343 may have a third air bag 343a. As an example, the third air bag 343a may be provided in the third air bag block 343. Also, the third air bag 343a may be connected to the third airline 163, and a third air pressure P3 (refer to FIG. 1) may be supplied to the third air bag 343a. For example, the third airline 163 may supply pressurized air to the third air bag 343a as the third air pressure P3. Meanwhile, the third air pressure P3 transferred to the third air bag 343a through the third airline 163 may be controlled by the controller 160.

As an example, an upper portion of the third air bag 343a may be opened, and an upper cover 343b covering the third air bag 343a may be provided above the opened third air bag 343a.

The fourth air bag block 344 may have a fourth air bag 344a. As an example, the fourth air bag 344a may be provided in the fourth air bag block 344. Also, the fourth air bag 344a may be connected to the fourth airline 164, and a fourth air pressure P4 (refer to FIG. 1) may be supplied to the fourth air bag 344a. For example, the fourth airline 164 may supply pressurized air to the fourth air bag 344a as the fourth air pressure P4. Meanwhile, the fourth air pressure P4 transferred to the fourth air bag 344a through the fourth airline 164 may be controlled by the controller 160.

As an example, an upper portion of the fourth air bag 344a may be opened, and an upper cover 344b covering the fourth air bag 344a may be provided above the opened fourth air bag 344a.

The controller 160 may control the first to fourth air pressures P1, P2, P3, and P4 supplied to the first to fourth air bags 341a, 342a, 343a, and 344a. As an example, the controller 160 may control the first air pressure P1 of the first air bag 341a, the second air pressure P2 of the second air bag 342a, the third air pressure P3 of the third air bag 343a, and the fourth air pressure P4 of the fourth air bag 344a to be equal to or different from each other. Accordingly, rigidities of the first to fourth air bags 341a, 342a, 343a, and 344a may be controlled by the controller 160 to be equal to or different from each other. Meanwhile, as an example, pneumatic control of the controller 160 for the first to fourth air bags 341a, 342a, 343a, and 344a may be determined according to tilting of the gimbaling part 200 (refer to FIG. 2). As an example, the controller 160 may receive control signals from a main controller (not shown) controlling operations of the conditioning apparatus 100.

The controller 160 and the main controller each may include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to other elements (e.g., keyboard, mouse, display, speakers, printers, modems, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the controller 160 and the main controller each can include antennas, network interfaces that provide wireless and/or wire line digital and/or analog interface to one or more networks over one or more network connections (not shown), a power source that provides an appropriate alternating current (AC) or direct current (DC) to power one or more components of the controller 160, and a bus that allows communication among the various disclosed components of the controller 160.

Meanwhile, the air bag module 340 may further include first and second elastic members 345 and 346 for returning the first air bag block 341, the second air bag block 342, the third air bag block 343, and the fourth air bag block 344 to original positions thereof, when air pressure is removed. The first elastic member 345 may be disposed below the first air bag block 341 and the second air bag block 342, and the second elastic member 346 may be disposed below the third air bag block 343 and the fourth air bag block 344.

The second frame 320 is coupled to one surface of the first frame 310. Meanwhile, the second frame 320 may include a first coupling portion 322 provided on one surface thereof, extending toward the first frame 310, and having a substantially cylindrical shape and a second coupling portion 324 provided on the other surface thereof and extending toward the third frame to be coupled to the third frame 300. In addition, the universal joint 400 may be insertedly disposed inside the first coupling portion 322 and the second coupling portion 324. For example, the universal joint 400 may be inserted into the first coupling portion 322 and the second coupling portion 324.

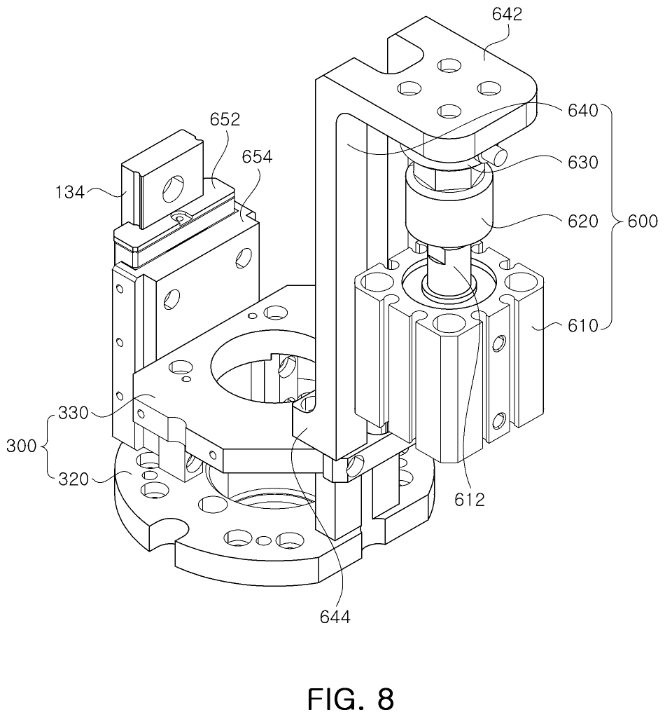

The third frame 330 may be coupled to one surface of the second frame 220 and may have a hollow ring shape. As an example, the third frame 330 may be fixedly installed on the second coupling portion 324. Meanwhile, the load applying unit 600 (refer to FIGS. 2 and 8) may be connected to an upper surface of the third frame 330.

In addition, on a bottom surface of the third frame 320, a connection member 654 (refer to FIGS. 2 and 8) connected to a sliding member 652 (refer to FIGS. 2 and 8) which is installed on a linear motion (LM) guide 134 (refer to FIG. 2) provided in the case 130 of the arm 110 and slidingly moves.

### Universal Joint and Rotation Driving Unit

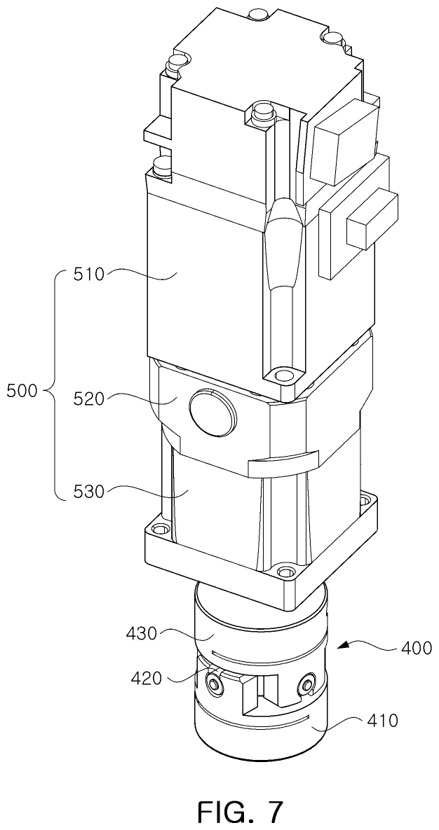

FIG. 7 is a perspective view illustrating a universal joint and a rotation driving unit provided in a conditioning apparatus according to an example embodiment.

First, referring to FIGS. 2 and 7, the universal joint 400 includes a first yoke 410, a cross shaft 420, and a second yoke 430, as an example. As an example, the universal joint 400 connects the gimbaling part 200 to the rotation driving unit 500 and serves to separate the center of gravity of the rotation driving unit 500 from the center of gravity MC of the gimbaling part 200. Accordingly, a distance between the center of gravity MC (refer to FIG. 2) of the gimbaling part 200 and the center C of the gimbaling part 200 may be reduced, thereby reducing a frictional moment and rotational inertia to reduce the occurrence of a perturbation phenomenon.

The coupling shaft portion 221 of the gimbaling part 200 is coupled to the first yoke 410, and two shafts provided in the cross shaft 942 are coupled. Meanwhile, the other two shafts, among four shafts provided on the cross shaft 942, are coupled to the second yoke 430. Also, a reduction shaft 540 (refer to FIG. 2) of the rotation driving unit 500 is coupled to the second yoke 430. In this manner, the rotation driving unit 500 may be connected to the gimbaling part 200 by the universal joint 400, so that the center of gravity of the rotation driving unit 500 may be separated from the center of gravity MC of the gimbaling part 200.

Next, referring to FIGS. 2 and 7, the rotation driving unit 500 includes, for example, a motor 510, a coupling 520, and a reducer 530.

The motor 510 generates driving force for rotating the gimbaling part 200, and a motor shaft 512 (refer to FIG. 2) provided in the motor 510 is connected to the coupling 520. Meanwhile, the coupling 520 serves to transfer the driving force generated by the motor 510 to the reducer 530, and to this end, the coupling 520 is disposed between the motor 510 and the reducer 530. The reducer 530 serves to reduce a rotational speed generated by the motor 510, and as an example, the reducer 530 serves to reduce a rotational force of the motor 510 to 1/10. The reducer 530 may be a mechanical reducer such as, for example, a gear box. However, a reduction ratio by the reducer 530 is not limited thereto and may be variously changed. Meanwhile, the reduction shaft 540 (refer to FIG. 2) provided in the reducer 530 may be connected to the second yoke 430 of the universal joint 400.

As described above, the rotation driving unit 500 may be connected to the universal joint 400 and may transfer driving force generated by the rotation driving unit 500 to the gimbaling part 200. Also, since the rotation driving unit 500 is connected to the gimbaling part 200 via the universal joint 400, the center of gravity (not shown) of the rotation driving unit 500 may be separated from the center of gravity MC of the gimbaling part 200.

### Load Applying Unit

FIG. 8 is a perspective view illustrating a load applying unit provided in A conditioning apparatus according to an example embodiment.

Referring to FIGS. 2 and 8, the load applying unit 600 includes a double-acting cylinder 610, a floating joint 620, a load cell 630, and a power transmission bar 640.

As an example, the double-acting cylinder 610 may be fixedly installed on an internal surface of the case 130 of the arm 110. In addition, the double-acting cylinder 610 serves to elevate the gimbaling part 200 in order to provide pressing force pressing a CMP pad (not shown) by the abrasive disc 140 installed in the gimbaling part 200. In addition, the floating joint 620 is connected to a piston 612 of the double-acting cylinder 610 and serves to absorb eccentricity and declination occurring when the piston 612 moves.

Meanwhile, the load cell 630 is disposed between the power transmission bar 640 and the floating joint 620 to detect pressure applied by the piston 612. The load cell 630 is connected to a main controller (not shown) and serves to transmit pressing force generated by the double-acting cylinder 610 to the main controller. Also, the main controller may control the pressing force pressing the CMP pad (not shown) by the abrasive disc 140 installed in the gimbaling part 200 according to information received from the load cell 630.

An extension portion 642 of the power transmission bar 640 is connected to the load cell 630, and a bracket portion 644 is installed on an upper surface of the third frame 330. Accordingly, when the piston 612 of the double-acting cylinder 610 moves up and down, the power transmission bar 640 may be moved up and down together with the piston 612. As such, when the power transmission bar 640 is moved up and down, the third frame 330 on which the power transmission bar 640 is installed may be moved up and down.

Meanwhile, the load applying unit 600 may include the sliding member 652 installed in the LM guide 134 provided in the case 130 of the arm 110 and slidably moving and a connection member 654 connecting the sliding member 652 to the third frame 330. Accordingly, movement of the frame unit 300 (refer to FIG. 2) by the power transmission bar 640 may be performed more smoothly.

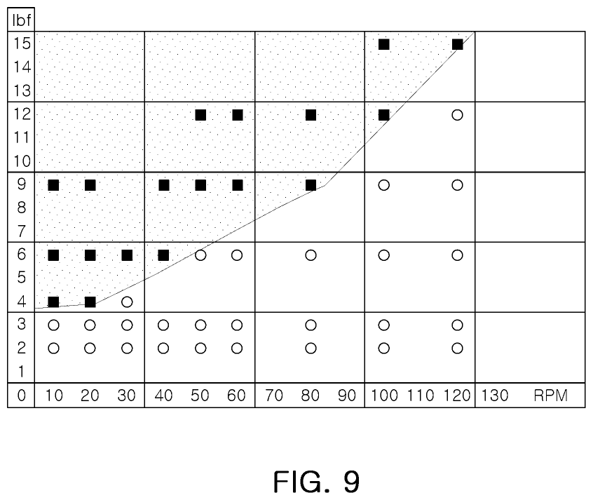

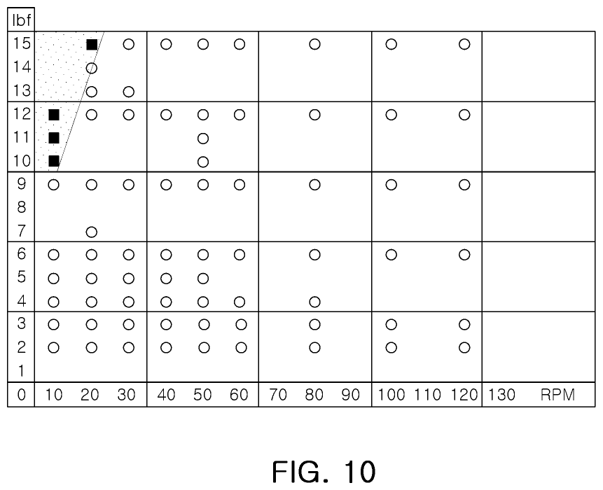

FIG. 9 is a graph illustrating performance of the conditioning apparatus according to the related art, and FIG. 10 is a graph illustrating performance of a conditioning apparatus according to an example embodiment of the present inventive concept.

Meanwhile, the horizontal axis of FIGS. 9 and 10 represents RPM of the CMP pad, and the vertical axis of FIGS. 9 and 10 represents conditioner down force (CDF). Meanwhile, among the values in FIGS. 9 and 10, hatched regions represent regions in which an acceleration value during an operation exceeds±1G (acceleration unit). In addition, a perturbation phenomenon occurs in the region in which the acceleration value exceeds±1G (acceleration unit).

Accordingly, when comparing FIG. 10 with FIG. 9, it can be seen that the region in which the perturbation phenomenon occurs rapidly decreases.

Meanwhile, as shown in the table below, it can be seen that, when the process condition of 6 lbf of CDF is applied, 86% was reduced in the case of the embodiment of the present inventive concept, compared to the related art, based on an acceleration (X direction) Max value at 40 PAD RPM.

| | | Embodiment of present |
|---|---|---|
| | Related art | inventive concept |
| Acceleration MAX at | 2.12 | 0.29 |
| 40 PAD RPM | | |
| Acceleration RM8 at | 0.64 | 0.058 |
| 10 to 60 PAD RPM | | |

In addition, it can be seen that, when the process condition of 6 lbf of CDF is applied, 91% was reduced in the case of the embodiment of the present inventive concept, compared to the related art, based on the acceleration root mean square (RMS) value at 10, 20, 30, 40, 50, and 60 PAD RPM.

As a result, it can be seen that the occurrence of the perturbation phenomenon may be reduced. Accordingly, it can be seen that low pressure conditioning may be effectively performed and advanced process control (APC) may be performed more effectively. Therefore, a pad life time (PLT) and a disc life time (DLT) may increase.

The conditioning apparatus capable of reducing the occurrence of a perturbation phenomenon may be provided.

While example embodiments have been shown and described above, it will be apparent to those skilled in the art that modifications and variations could be made without departing from the scope of the present inventive concept as defined by the appended claims.

What is claimed is:

1. A conditioning apparatus comprising:
an arm configured to be rotated by an actuator;
a gimbaling part disposed at one end of the arm and disposed such that a lower end thereof protrudes outwardly of the arm and an abrasive disc is installed thereon;
a frame unit connected to the gimbaling part;
a rotation driving unit connected to the gimbaling part and configured to transfer driving force for rotating the abrasive disc;
a load applying unit connected to the frame unit and configured to elevate the frame unit; and
a universal joint connecting the gimbaling part to the rotation driving unit,
wherein the universal joint separates a center of gravity of the rotation driving unit from a center of gravity of the gimbaling part.

2. The conditioning apparatus of claim 1, wherein the gimbaling part includes:
a disc holder having one surface on which the abrasive disc is installed and having an other surface on which a coupling shaft portion connected to the universal joint is provided;
a housing disposed around the disc holder;
a first bearing disposed inside the housing; and
a second bearing disposed inside the first bearing.

3. The conditioning apparatus of claim 2, wherein the disc holder includes:
a disc holder body including a protrusion from which the coupling shaft portion extends and a protruding wall portion disposed to surround the protrusion;
a first installation member forming a space in which the first bearing is installed together with the protruding wall portion; and
a second installation member forming a space in which the second bearing is installed together with the protrusion.

4. The conditioning apparatus of claim 3, wherein a first fixing member preventing separation of the first bearing is installed on an upper surface of the protruding wall portion.

5. The conditioning apparatus of claim 2, wherein the first ball bearing is a deep groove ball bearing.

6. The conditioning apparatus of claim 2, wherein the second ball bearing is a self-aligning ball bearing.

7. The conditioning apparatus of claim 1,
wherein the frame unit includes:
a first frame having a hollow ring shape;
a second frame coupled to one surface of the first frame; and
a third frame coupled to one surface of the second frame and having a hollow ring shape, and
wherein the second frame includes a first coupling portion disposed on one surface and coupled to the first frame and a second coupling portion disposed on an other surface and coupled to the third frame.

8. The conditioning apparatus of claim 7, wherein the universal joint includes a lower end disposed inside the second coupling portion of the second frame.

9. The conditioning apparatus of claim 7, wherein an air bag module is disposed between the first frame and the second frame to compensate for tilting of the gimbaling part.

10. The conditioning apparatus of claim 9, wherein the air bag module is connected to an airline for providing air pressure.

11. The conditioning apparatus of claim 9, wherein the air bag module includes a plurality of air bag blocks spaced apart from each other in a circumferential direction.

12. The conditioning apparatus of claim 1,
wherein the rotation driving unit includes:
a motor generating rotational force;
a coupling to which a motor shaft of the motor is connected; and
a reducer coupled to the coupling to reduce a rotational speed of the motor, and
wherein the reducer is connected to the universal joint.

13. The conditioning apparatus of claim 1, wherein the load applying unit includes:
a double-acting cylinder generating driving force;
a floating joint connected to the double-acting cylinder;
a load cell coupled to the floating joint; and
a power transmission bar having one end connected to the load cell and an other end connected to the frame unit.

14. The conditioning apparatus of claim 13, wherein the load applying unit includes a sliding member coupled to a linear motion (LM) guide fixed to an internal surface of the arm and configured to slide according to elevation of the power transmission bar.

15. The conditioning apparatus of claim 14, wherein the load applying unit includes a connection member connecting the sliding member to a third frame provided in the frame unit.

16. The conditioning apparatus of claim 1, further comprising a displacement sensor connected to the frame unit.

17. A conditioning apparatus comprising:
an arm configured to be rotated by an actuator;
a gimbaling part disposed at one end of the arm and disposed such that a lower end thereof protrudes outwardly of the arm and an abrasive disc is installed thereon;
a frame unit connected to the gimbaling part;
a rotation driving unit connected to the gimbaling part and configured to transfer driving force for rotating the abrasive disc;
a load applying unit connected to the frame unit and configured to elevate the frame unit; and
a universal joint connecting the gimbaling part to the rotation driving unit,
wherein the universal joint includes a first yoke connected to the gimbaling part, a second yoke disposed above the first yoke and connected to the rotation driving unit, and a cross shaft connecting the first yoke to the second yoke,
wherein the universal joint separates the center of gravity of the rotation driving unit from the center of gravity of the gimbaling part,
wherein the gimbaling part includes a disc holder having one surface on which the abrasive disc is installed and an other surface on which a protrusion is provided, a coupling shaft portion connected to the universal joint extending from the protrusion, and
wherein the center of gravity of the gimbaling part and the center of the gimbaling part are disposed within the protrusion.
